(19) United States
(12) Patent Application Publication
(10) Pub. No.: US 2008/0012031 A1
(43) Pub. Date: Jan. 17, 2008

(54) WHITE LIGHT-EMITTING DIODE USING SEMICONDUCTOR NANOCRYSTALS AND PREPARATION METHOD THEREOF

(75) Inventors: Eun Joo Jang, Suwon-si (KR); Byung Ki Kim, Gunpo-si (KR); Shin Ae Jun, Seongnam-si (KR); Jung Eun Lim, Seongnam-si (KR)

Correspondence Address: CANTOR COLBURN, LLP, 55 GRIFFIN ROAD SOUTH, BLOOMFIELD, CT, 06002, US

(73) Assignee: SAMSUNG ELECTRONICS CO., LTD., Suwon-si (KR)

(21) Appl. No.: 11/679,510

(22) Filed: Feb. 27, 2007

(30) Foreign Application Priority Data
Jul. 14, 2006 (KR) 10-2006-0066231

(51) Int. Cl. H01L 33/00; H01L 21/00

(52) U.S. Cl. 257/89; 438/26; 257/E33.061; 257/E21.002; 977/949

(57) ABSTRACT

Disclosed are a white light-emitting diode (LED) in which an emission layer comprising a red luminous body and a green luminous body is formed on a blue LED, and a preparation method thereof. The emission layer comprises both of at least one inorganic phosphor and at least one semiconductor nanocrystal. The white LED prepared according to the present invention has excellent color purity, high luminous efficiency and improved light stability so that it can be advantageously used as a light source for various display devices.

This non-provisional application claims priority to Korean Patent Application No. 10-2006-0066231, filed on Jul. 14, 2006, under 35 U.S.C. § 119 and all the benefits accruing therefrom, the content of which is incorporated herein by reference in its entirety.

### BACKGROUND OF THE INVENTION

1. Field of the Invention

The present invention relates to a white light-emitting diode (“LED”) using semiconductor nanocrystals and a preparation method thereof. More specifically, the present invention is directed to a white LED using semiconductor nanocrystals, in which an emission layer formed on a blue LED includes semiconductor nanocrystals as a luminous body so that the white LED has improved color purity and luminous efficiency, and a preparation method thereof.

2. Description of the Related Art

A white LED using a semiconductor has come into the spotlight as one of next generation light-emitting devices capable of replacing the conventional light-emitting device because it has a long life span, a small size, low power consumption, and environmental-friendly characteristics in that it uses no mercury. A white LED has been used in the backlight of a liquid crystal display (“LCD”), the dashboard of a car, and the like.

In particular, there have been proposed methods using all three-color (red, green and blue) LEDs having a good luminous efficiency and color purity in order to use them as the backlight of an LCD. However, these methods have some disadvantages that the production cost is high and an operation circuit thereof is complex, which have very low price competitiveness. Therefore, a need has existed for development of a one-chip solution that can reduce the production cost and simplify the structure of the circuit device while maintaining good luminous efficiency and color purity, as in existing methods.

As one solution, a white LED was developed wherein a YAG:Ce phosphor is combined with an InGaN based blue LED having a wavelength of 450 nanometers (nm). This LED is operated under the principle that some of blue light generated from the LED causes the YAG:Ce phosphor to be excited, thereby producing a yellowish green color, and the green color combines with the yellowish green color to provide a white color. However, since the light of the white LED, in which the blue LED is combined with the YAG:Ce phosphor, emits only a portion of the area under the visible spectrum, the color rendering index is low and efficiency is reduced. As a result, if the white light emitted by the blue LED combined with the YAG:Ce phosphor is passed through a color filter of red, green and blue colors, many of the emitted wavelengths cannot pass through the filter and can result in inadequate color transmission and display properties. Such an LED is of limited use in that it is not applicable for display devices such as a television requiring a high quality due to the low color purity caused by the above-mentioned disadvantages.

Recently, a method for producing a white LED has been developed that uses an ultraviolet LED that is expected to have high energy efficiency as an excitation source instead of a blue LED, and further using blue, green, and red luminous bodies. However, there has been a demand for developing a red luminous body having more efficiency than the blue and green luminous bodies.

In another method, a method for coating green and red inorganic phosphors on the blue LED has been attempted. However, no materials were developed that were capable of exciting an inorganic phosphor, which requires a relatively high excitation energy, with a blue wavelength of visible ray area. Moreover, green phosphors developed so far exhibit low stability and poor color purity, and red phosphors are less efficient relative to phosphors emitting in other colors. Therefore, this method does not solve the existing problems, and thus the method is limited in that it is very difficult to ensure the color purity and luminous efficiency required by an LED for use in a backlight unit.

LED devices which use highly efficient nanocrystals with a quantum confinement effect as a new light-emitting material are disclosed in U.S. Pat. No. 6,890,777, which discloses white and colored LEDs that employ a first light source, a host matrix and a population of quantum dots embedded in the host matrix. However, when the LED employing these quantum dots is exposed to a high-energy light source for a long time, the luminous efficiency is decreased dramatically.

### BRIEF SUMMARY OF THE INVENTION

Therefore, an aspect of the present invention includes providing a white LED capable of stably maintaining a white light while having excellent color purity and high luminous efficiency, and a backlight unit and a display device using the same.

Another aspect of the present invention includes providing a method capable of economically producing a white LED having excellent color purity, and high luminous efficiency and light stability by using both an inorganic phosphor and semiconductor nanocrystals as a luminous body.

In an exemplary embodiment, a white LED includes an emission layer comprising a red luminous body and a green luminous body formed on a blue LED, wherein the emission layer includes at least one inorganic phosphor and at least one semiconductor nanocrystal.

The red luminous body of the emission layer can include either or both of a red phosphor and red light-emitting semiconductor nanocrystals, and the green luminous body can include either or both of a green phosphor and green light-emitting semiconductor nanocrystals.

In such a structure, in order that the green inorganic phosphor can absorb an emission wavelength of the blue LED before the red light-emitting semiconductor nanocrystals absorb the emission wavelength, it can be configured in such a way that the emission layer comprises a green luminous body layer comprising the green luminous body formed on the blue LED, and a red luminous body layer comprising the red luminous body formed on the green luminous body layer on a side opposite the blue LED.

Furthermore, the emission layer can comprise a mixed luminous body layer comprising the red luminous body and the green luminous body formed on the blue LED and a red luminous body layer comprising the red luminous body, formed on the mixed luminous body layer on a side opposite the blue LED, or can comprise a mixed luminous body layer comprising the red luminous body and the green luminous body, and a green luminous body layer comprising the green luminous body formed on the mixed luminous body layer on a side opposite the blue LED.

In this structure, when a red inorganic phosphor and green light-emitting semiconductor nanocrystals are used, the same structure may be applied to prolong the life span thereof.

At least one of the green light-emitting semiconductor nanocrystals and the red light-emitting semiconductor nanocrystals can be semiconductor nanocrystals of multi-layered structure including two or more light-emitting materials.

According to another exemplary embodiment of the present invention, a method for producing a white LED includes: providing a blue LED; and forming an emission layer comprising a red luminous body and a green luminous body on the blue LED, wherein forming the emission layer includes forming a luminous body layer by using either or both of a red phosphor or red light-emitting semiconductor nanocrystals as the red luminous body and further using either or both of a green phosphor or green light-emitting semiconductor nanocrystals as the green luminous body, at least one inorganic phosphor and at least one semiconductor nanocrystal being included in the luminous body layer simultaneously.

Semiconductor nanocrystals having a multi-layered structure comprising two or more light-emitting materials may be used as the green or red light-emitting semiconductor nanocrystals used in the luminous body layer.

According to other exemplary embodiments, a backlight unit includes the white LED; and a display device includes the same.

### BRIEF DESCRIPTION OF THE DRAWINGS

The above and other aspects, features, and other advantages of the present invention will be more clearly understood from the following detailed description taken in conjunction with the accompanying drawings, in which:

FIG. 1 is a schematic illustration of an exemplary embodiment of a white LED according to the present invention;

FIG. 2 is a schematic illustration of another exemplary embodiment of a white LED according to the present invention;

FIG. 3 is a schematic illustration of another still exemplary embodiment of a white LED according to the present invention;

FIGS. 4A to 4C are schematic illustrations of exemplary embodiments of semiconductor nanocrystals having multi-layered structures;

FIGS. 5A to 5C are schematic illustrations of exemplary embodiments of semiconductor nanocrystals of multi-layered structure, in which an alloyed interlayer has a compositional gradient;

FIG. 6 is a schematic illustration of a cross section of an exemplary embodiment of an LED according to the present invention;

FIG. 7 is a schematic illustration of a cross-section of another exemplary embodiment of an LED according to the present invention;

FIG. 8A includes absorption and emission spectra of the exemplary embodiment of a green light-emitting semiconductor nanocrystals obtained in Preparation Example 1;

FIG. 8B includes absorption and emission spectra of the exemplary embodiment of a red light-emitting semiconductor nanocrystals obtained in Preparation Example 2;

FIG. 9 is a graph showing a change in luminescence intensity in terms of time in exciting the exemplary embodiment of the red light-emitting semiconductor nanocrystals obtained in Preparation Example 2 by a blue light source;

FIG. 10 is an emission spectrum of an exemplary embodiment of an LED device using the green light-emitting semiconductor nanocrystals produced in Example 1;

FIG. 11 is an emission spectrum of an LED device using a green inorganic phosphor produced in Comparative Example 1;

FIG. 12 is an emission spectrum of an exemplary embodiment of an LED device using the red light-emitting semiconductor nanocrystals produced in Example 2;

FIG. 13 is an emission spectrum of an LED device using the red inorganic phosphor produced in Comparative Example 2;

FIG. 14 is an emission spectrum of the exemplary embodiment of an LED device produced in Example 3; and

FIG. 15 shows an emission spectrum of the exemplary embodiment of an LED device produced in Example 4.

### DETAILED DESCRIPTION OF THE INVENTION

Hereinafter, the present invention will be described more fully with reference to the accompanying drawings, in which exemplary embodiments of the present invention are shown. This invention may, however, be embodied in many different forms and should not be construed as limited to the exemplary embodiments set forth herein. Rather, these exemplary embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present there between. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprise”, “comprises”, and “comprising,” when used in this specification, specify the presence of stated features, integers, steps, operations, elements, components, and/or combination of the foregoing, but do not preclude the presence and/or addition of one or more other features, integers, steps, operations, elements, components, groups, and/or combination of the foregoing.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In an exemplary embodiment, a white light-emitting diode (LED), in which an emission layer comprising a red luminous body and a green luminous body is formed on a blue LED, is characterized in that the emission layer comprises both of at least one inorganic phosphor and at least one semiconductor nanocrystal.

Also, the red luminous body may comprise either or both of a red phosphor or red light-emitting semiconductor nanocrystals, and the green luminous body may comprise either or both of a green phosphor or green light-emitting semiconductor nanocrystals.

The green luminous body and the red luminous body are excited by light radiated (emitted) from the blue LED to thereby emit a green light and a red light, respectively; and a white light is realized by combining these radiated lights with a blue light that is passed through the emission layer.

The wavelength of the blue LED can be used as a constituent wavelength of a white light, where the green luminous body absorbs only a portion of the blue wavelength of the blue LED and thereby emits a light of a green and a blue wavelength which can be used as a constituent wavelength of the white light. The red luminous body absorbs only a portion of the blue wavelength of the blue LED to thereby emit a light of red wavelength, or the red luminous body again absorbs only a portion of a light of green wavelength emitted from a green luminous body after the green luminous body absorbs only a portion of the blue wavelength of the blue LED, and thereby the red luminous body emits a light of red wavelength which can be used as a constituent wavelength of the white light.

While semiconductor nanocrystals have excellent luminous efficiency and high color purity, they are limited in that the luminous efficiency diminishes upon use by a high-energy excitation light source over time. Therefore, if an ultraviolet LED is used as the excitation light source, it is necessary that a luminous body that emits blue, green, and red lights respectively converts all excitation light sources belonging to ultraviolet light into the lights of respective wavelengths, which reduces the life span of the luminous body.

However, the present invention uses a blue LED as the excitation light source to enhance the life span of the semiconductor nanocrystals. Thus, since a portion of the emission wavelengths of the blue light source constitute the white light, the green luminous body and the red luminous body convert only some of the blue light source emission into light of respective wavelengths so that the life span of the semiconductor nanocrystals is improved, thereby making it possible to fully utilize the advantages of semiconductor nanocrystals.

In case where a blue LED is used as the excitation light source and a single emission layer is coated on the blue LED from a uniform mixture of a green inorganic phosphor and red light-emitting semiconductor nanocrystals, the green inorganic phosphor absorbs some of the blue emission wavelength to emit light of a green wavelength. Thus, the red light-emitting semiconductor nanocrystals convert only a portion of the blue emission wavelength into a red wavelength, thereby improving the life span of semiconductor nanocrystals.

Alternatively, in such a structure, the green inorganic phosphor absorbs some of the blue emission wavelength and emits a light of a green wavelength. The red light-emitting semiconductor nanocrystals further absorb some of the green wavelength light, using the green wavelength light as an excitation light source and convert it to a red light. Thus, it is possible to absorb and use a green excitation light source having lower energy than the blue excitation light source, thereby enhancing the life span of semiconductor nanocrystals.

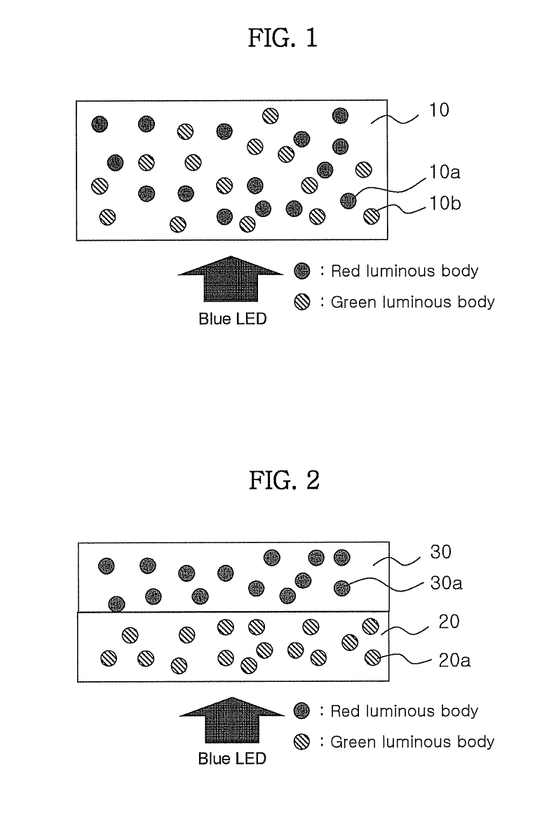

In the present invention, the emission layer can be designed in various structures. For example, the emission layer is composed of a mixed luminous body layer 10 of a red luminous body 10a and a green luminous body 10b, as shown in FIG. 1.

As described in detail hereinabove, the emission layer in the white LED is composed of the inorganic phosphor and the semiconductor nanocrystals. Therefore, if the emission layer is composed of the mixed luminous body layer 10 of the red luminous body 10a and the green luminous body 10b, such mixed luminous body layer 10 may be composed of, in one embodiment, one inorganic phosphor (e.g., a green inorganic phosphor or red inorganic phosphor) and a semiconductor nanocrystal (e.g., red light-emitting semiconductor nanocrystals or green light-emitting semiconductor nanocrystals), or two inorganic phosphors (e.g., green inorganic phosphor and red inorganic phosphor) and one semiconductor nanocrystal (e.g., red light-emitting semiconductor nanocrystals or green light-emitting semiconductor nanocrystals). Alternatively, in another embodiment, the mixed luminous body layer 10 may be composed of an inorganic phosphor and two semiconductor nanocrystals, or two inorganic phosphors and two semiconductor nanocrystals.

The emission layer may be composed of multiple layers, wherein one example of LED in this case is shown in FIG. 2. With reference to FIG. 2, the emission layer can include a green luminous body layer 20 having a green luminous body 20a formed on a blue LED and a red luminous body layer 30 having a red luminous body 30a formed on the green luminous body layer 20 on a side opposite the blue LED.

At this time, a red inorganic phosphor or red light-emitting semiconductor nanocrystals can be used alone as the red luminous body 30a, or the red phosphor can be used with the red light-emitting semiconductor nanocrystals. Meanwhile, a green inorganic phosphor or green light-emitting semiconductor nanocrystals can be used alone as the green luminous body 20a, or the green phosphor can be used with green light-emitting semiconductor nanocrystals. Therefore, in the example shown in FIG. 2, the green luminous body layer 20 may comprise of the green phosphor and the red luminous body layer may comprise the red light-emitting semiconductor nanocrystals, or the green luminous body layer 20 may comprise the green light-emitting semiconductor nanocrystals and the red luminous body layer 30 may comprise the red phosphor and red light-emitting semiconductor nanocrystals.

On the other hand, since the red light-emitting semiconductor nanocrystals can emit a red light upon absorbing a green emission wavelength emitted from the green luminous body layer, it is possible to use green light, which has a lower energy than blue light, as the excitation light source of semiconductor nanocrystals thereby improving the stability of nanocrystals. Thus, as one example, the green luminous body layer 20 may be composed of the green inorganic phosphor and the red luminous body layer 30 may be composed of the red light-emitting semiconductor nanocrystals.

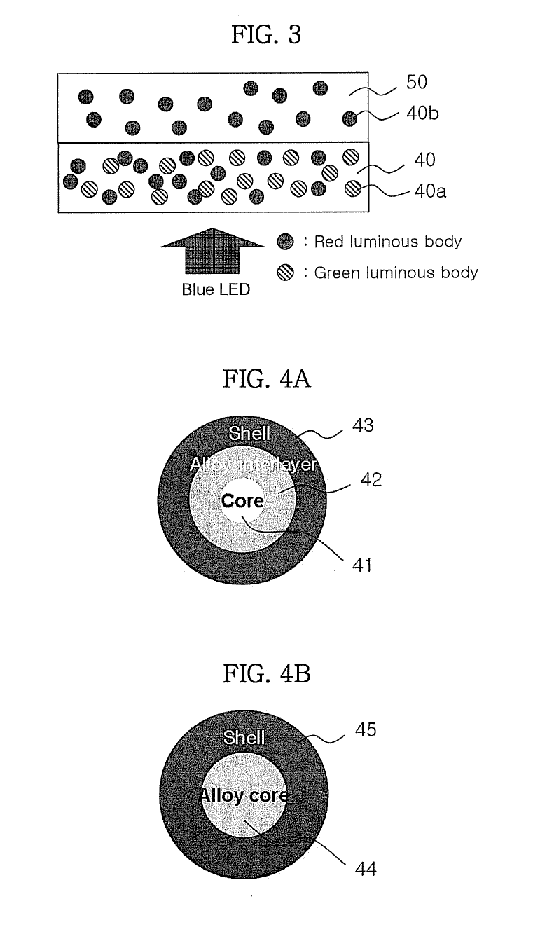

In another embodiment, as shown in FIG. 3, the emission layer can comprise a mixed luminous body layer 40 of a red luminous body 40a and a green luminous body 40b, and a red luminous body layer 50 comprising red luminous body 40a formed on the mixed luminous body layer 40. Alternatively, the emission layer may comprise a mixed luminous body layer of a red luminous body 40a and a green luminous body 40b, and a green luminous body layer 50 formed on the mixed luminous body layer 40. If the luminous efficiency of light of a green region irradiated from the mixed luminous body layer is low, it is preferable to have a green luminous body layer formed on the mixed luminous body layer. If the luminous efficiency of light of a red region irradiated from the mixed luminous body layer is low, it is preferable to have a red luminous body layer 50 formed on the mixed luminous body layer 40.

Semiconductor nanocrystals used as a luminous body may be of a multi-layered structure having at least two light-emitting materials. That is, red light-emitting semiconductor nanocrystals or green light-emitting semiconductor nanocrystals may be included in semiconductor nanocrystals of multi-layered structure. As used herein, the term “semiconductor nanocrystals” mean nanocrystals which have a layered structure of at least two adjacent layers, each of which is composed of a different type of light-emitting material, and which includes at least one alloy interlayer located at the interface of the adjacent layers.

The semiconductor nanocrystals having the multi-layered structure is structurally stable as provided for by the alloy interlayer, which is formed at the interface where the different light-emitting materials form a crystal structure, and therefore, the stress resulting from the difference in crystal phase is small. Thus, the LED comprising the semiconductor nanocrystals of multi-layered structure has a superior light stability, so that it can maintain stable luminous properties for a long period of time where a blue LED is included as an excitation source. Further, since the semiconductor nanocrystals having a multi-layered structure can absorb energy from an area similar in size to the emission wavelength, it can utilize energy transfer that occurs when it is used with the inorganic phosphor.

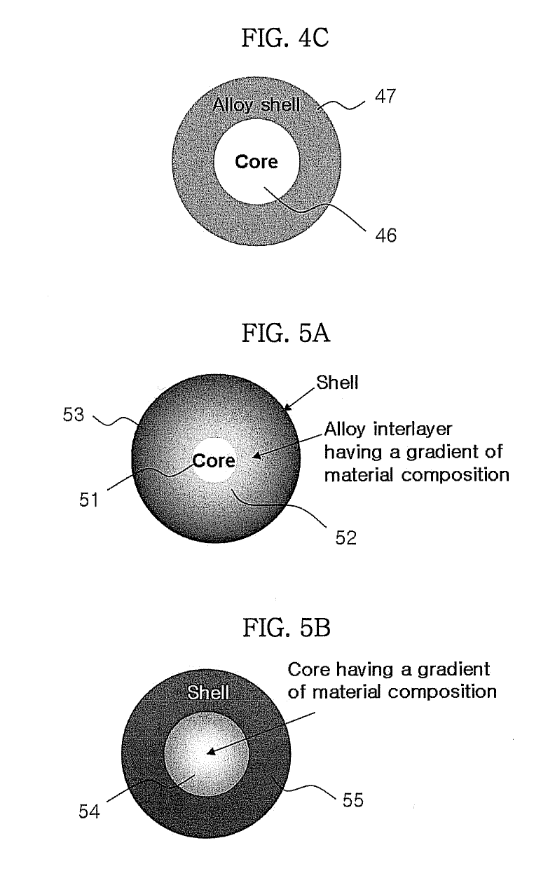

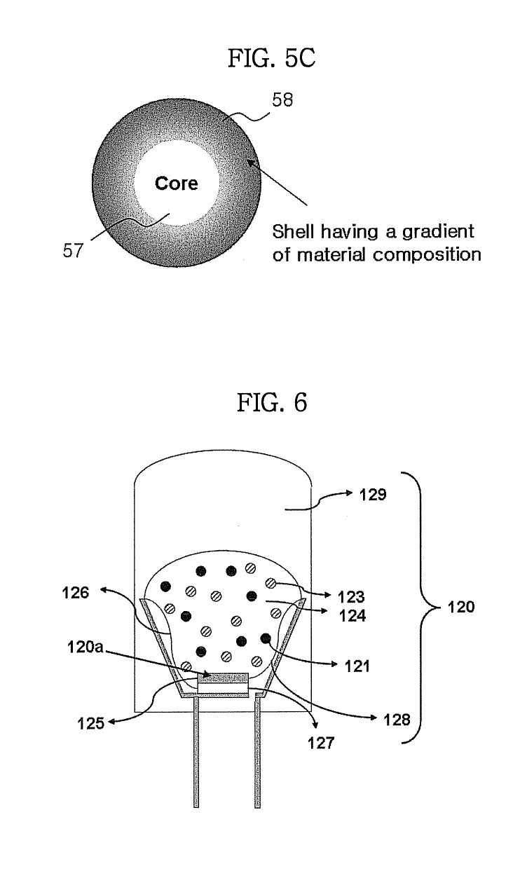

In the present invention, the semiconductor nanocrystals of multi-layered structure may have a varied shape such as a sphere (FIGS. 4A to 4C and FIGS. 5A to 5C), tetrahedron, cylinder, rod, triangle, disc, tripod, tetrapod, cube, box, star, tube, or the like, but as it is generally understood that the sphere structure has the highest luminous efficiency, in a specific embodiment, the semiconductor nanocrystals may have a spherical shape.

The semiconductor nanocrystals of multi-layered structure can include the alloy interlayer comprising at least two materials (i.e., core and shell materials) in the interface between the adjacent layers, in which the alloy interlayer consists of the different light-emitting materials in intimate contact with each other, and where the interlayer is in intimate contact with the adjacent layers. Such an alloy interlayer buffers the differences of lattice constant between the light-emitting materials that constitute the nanocrystals, thereby enhancing the light-emitting material stability.

FIGS. 4A to 4C show semiconductor nanocrystals having, in an embodiment, a spherical structure. The spherical semiconductor nanocrystals have a core-shell structure, and can comprise an alloy interlayer 42 in an interface between the core 41 and the shell 43, as shown in FIG. 4A. If a volume of the core 41 is small or a velocity for diffusion of the shell 43 into the core 43 is more rapid, the alloy interlayer 42 is diffused into the center portion of the core 41, whereby an alloy core-shell structure can be formed. That is, the semiconductor nanocrystals, as shown FIG. 4B, are composed of an alloy core 44 and a shell 45 surrounding the alloy core 44.

Meanwhile, if the shell is thin or if velocity for diffusion of the core into the shell (i.e., if the diffusivity of the core material) is more rapid, the alloy interlayer diffuses into the outer portion of shell whereby a core-alloy shell structure can be formed. That is, the semiconductor nanocrystals, as shown FIG. 4C, are composed of a core 46 and an alloy shell 47 surrounding the core 46.

In the present invention, the alloy interlayer can be a gradient alloy interlayer having a compositional gradient of light-emitting material composition. As used herein, the phrase “compositional gradient” means a change in concentration across the interlayer for the different light-emitting materials present in the interlayer, which varies through the interlayer depending on the proximity of a region in the interlayer to an adjacent layer. For example, in a structure having a first and second layer with an interlayer between, the concentration of a first light emitting material in the first layer (e.g., in a core) is highest in the part of an interlayer nearest the first layer, and lowest in a part of the interlayer furthest from the core; likewise, the concentration of a second light emitting material present in the second layer is highest in the part of the interlayer nearest the second layer, and lowest in the region of the interlayer nearest the first layer. FIGS. 5A to 5C show a gradient structure of spherical semiconductor nanocrystals having a gradient of light-emitting material composition wherein an alloy interlayer does not form a uniform alloy phase. In the semiconductor nanocrystals having such structure, as shown in FIG. 5A, an alloy interlayer 52 having a gradient of light-emitting material composition can also be formed in an interface between a core 51 and a shell 53. Moreover, as shown in FIG. 5B, semiconductor nanocrystals can have a structure where a core 54 is an alloy interlayer having a gradient of light-emitting material composition and a shell 55 is formed around the core 54. In another embodiment as shown in FIG. 5C, a core 57 of semiconductor nanocrystals in the core-shell structure can consist of one material and a shell 58 can consist of an alloy interlayer having a gradient of light-emitting material composition.

In the present invention, any materials may be used as semiconductor nanocrystals as long as they exhibit a quantum confinement effect by their nano-size. More specifically, the materials useful for semiconductor nanocrystals can be selected from the group consisting of group II-VI (also referred to as a “group 12-16”) compound, group III-V (also referred to as a “group 13-15”) compound, group IV-VI (also referred to as a “group 14-16”) compound, group IV (also referred to as a “group 14”) compound, and a mixture thereof.

Examples of group II-VI compound include binary compounds such as CdSe, CdTe, ZnS, ZnSe, ZnTe, ZnO, HgS, HgSe, HgTe, etc.; or trinary compounds such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, or the like; or quaternary compounds such as HgZnTe, CdZnSeS, CdZnSeTe, CdZnSTe, CdHgSeS, CdHgSeTe, CdHgSTe, HgZnSeS, HgZnSeTe, HgZnSTe, or the like.

Examples of group III-V compound semiconductor include binary compounds such as GaN, GaP, GaAs, GaSb, AlN, AlP, AlAs, AlSb, InN, InP, InAs, InSb, etc.; or trinary compounds such as GaNP, GaNAs, GaNSb, GaPAs, GaPSb, AINP, AlNAs, AlNSb, AlPAs, AIPSb, InNP, InNAs, InNSb, InPAs, InPSb, or the like; or quaternary compounds such as GaAlNP, GaAlNAs, GaAlNSb, GaAlPAs, GaAlPSb, GaInNP, GaInNAs, GaInNSb, GalnPAs, GalnPSb, InAlNP, InAlNAs, InAlNSb, InAlPAs, InAlPSb, or the like.

Examples of group IV-VI compound may include materials selected from the group consisting of binary compounds such as SnS, SnSe, SnTe, PbS, PbSe, PbTe, etc.; trinary compounds such as SnSeS, SnSeTe, SnSTe, PbSeS, PbSeTe, PbSTe, SnPbS, SnPbSe, SnPbTe, or the like; and quaternary compound such as SnPbSSe, SnPbSeTe, SnPbSTe, or the like. The group IV compound includes materials selected from the group consisting of single element compound such as Si, Ge, or the like, and binary compounds such as SiC, SiGe, or the like.

In the following description, the nanocrystals of multi-layered structure according to the present invention are referred to as “CdSe//ZnS”. That is, such an expression having two consecutive forward slashes between two chemical formulae means herein that an alloy interlayer was formed between for example the CdSe nanocrystal and the ZnS nanocrystal.

Red light-emitting semiconductor nanocrystals and green light-emitting semiconductor nanocrystals can adjust emission wavelength by changing a size and composition of semiconductor nanocrystals. For example, semiconductor nanocrystals having a diameter of 2 to 30 nm can be used as the red light-emitting semiconductor nanocrystals, and semiconductor nanocrystals having a diameter of 2 to 30 nm can be used as the green light-emitting semiconductor nanocrystals. Especially, in semiconductor nanocrystals having a multi-layered structure, when the shell material is diffused into the core material (or wherein the core material is diffused into the shell material), the chemical composition of the emission core is changed, thereby changing the emission wavelength of the semiconductor nanocrystal.

Groups II-VI, III-V, IV-VI and IV elements constituting semiconductor nanocrystals have an energy band gap that is their intrinsic property, and can show the property that they emit a light in the process that they are stabilized after the energy transition occurs depending on such an energy band gap. In particular, when the semiconductor material is made in a structure with a size of 2 to 30 nm, the quantum confinement effect is shown and then the intrinsic energy band gap of the material is changed. Furthermore, as quantized energy level is created, the energy density increases so that the wavelength emitting a light is changed and thus a luminous efficiency can be increased. That is, the energy band gap can be controlled by adjusting the components (i.e., the composition) constituting the semiconductor nanocrystals as well as adjusting the size thereof.

Red fluors useful in the present invention include (Y,Gd)BO₃:Eu, Y(V,P)O₄:Eu, (Y,Gd)O₃:Eu, La₂O₂S:Eu³⁺, Mg₄(F)GeO₈:Mn, Y₂O₃:Ru, Y₂O₂S:Eu, K₅Eu_{2.5}(WO₄)_{6.25}:Sm_{0.08}, YBO₃SrS:Eu²⁺ or the like, but in a specific embodiment, it is preferable to use (Y,Gd)BO₃:Eu, which shows excellent brightness properties.

The green phosphor of the present invention can be one or more materials selected from the group consisting of BaMgAl₁₀O₁₇:Eu,Mn, Zn₂SiO₄:Mn, (Zn,A)₂SiO₄:Mn (where A is an alkaline earth metal), MgAlₓO_{y}:Mn (where x is an integer of 1 to 10, and y is an integer of 1 to 30), LaMgAlₓO_{y}:Tb (where x is an integer of 1 to 14 and y is an integer of 8 to 47), X_{Re}BO₃:Tb (where X_{Re} is at least one rare earth element selected from the group consisting of Sc, Y, La, Ce and Gd), ZnS:Cu:Al, SrGa₂S₄:Ru, Tb(SrGa₂S₄:Eu²⁺), and (Y,Gd)BO₃:Tb.

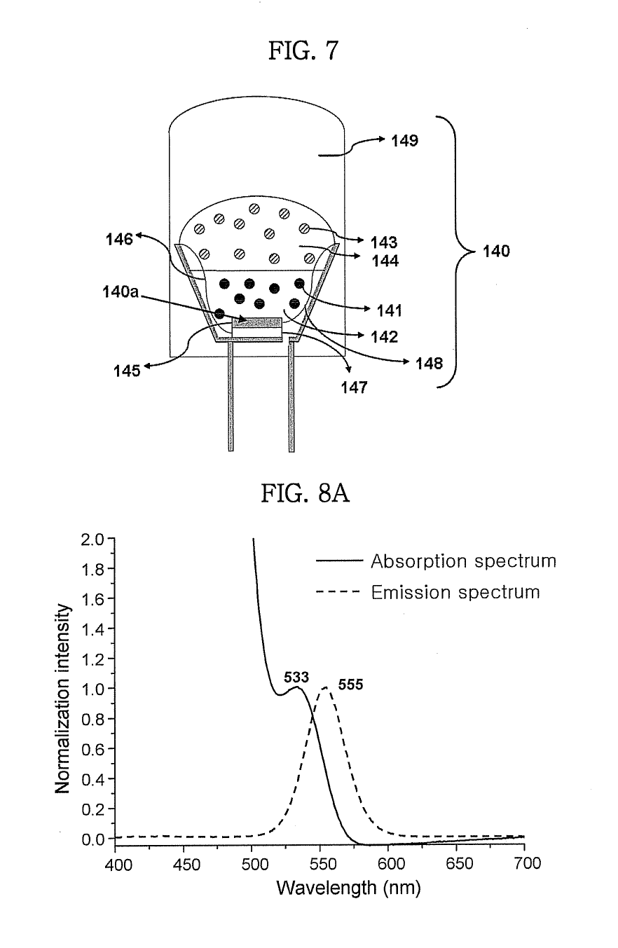

FIG. 6 shows a schematic cross-sectional view of an LED 120 according to one embodiment of the present invention in which the green luminous body 121 and red luminous body 123 are distributed homogeneously throughout a transparent resin matrix 124, and FIG. 7 shows a schematic cross-sectional view of an LED 140 according to another embodiment of the present invention, which employs a layer of a green luminous body 141 and a layer having a red luminous body 143 in which the layers are separate from each other.

As shown in FIG. 6, the LED 120 according to one embodiment of the present invention comprises a mixed luminous body layer 129 which includes a blue LED chip 120a having a p-type semiconductor 125 and an n-type semiconductor 127 located on the surface of a substrate (not shown), and a transparent resin matrix 124 having a luminous body covering the blue LED chip 120a. The transparent resin matrix 124 of the mixed luminous body layer 129 includes both a green luminous body 121 and a red luminous body 123. The p-type semiconductor 125 of the blue LED chip 120a is electrically connected to an electrode via a wire 126, and the n-type semiconductor 127 is electrically connected to an electrode via a wire 128.

In another embodiment as shown in FIG. 7, an emission layer can be formed from a separate green luminous body layer and red luminous body layer. In such an embodiment, an emission layer 149 is configured to have a transparent resin matrix 142 including a green luminous body 141 and a transparent resin matrix 144 including a red luminous body 143, as shown in FIG. 7. In FIG. 7, reference numeral 145 indicates a p-type semiconductor and reference numeral 146 denotes a wire for electrically connecting the p-type semiconductor 145 to an electrode. Further, reference numeral 147 indicates an n-type semiconductor and reference numeral 148 indicates a wire for electrically connecting the n-type semiconductor 147 to an electrode.

The white LED of the present invention can be utilized in a backlight unit of any of a variety of display devices such as an LCD or the like. The backlight unit of an LCD has a flat light guide plate prepared on the surface of the substrate, and the LED is located on the side of the light guide plate. Normally, several LEDs are arranged in an array form. Since the white LED of the present invention has excellent color purity and luminous efficiency, it can be applied to a large area LCD that requires a varied color reproduction, in addition to a backlight unit of a small-sized display such as cell phone. Moreover, the white LED of the invention can be used in a wide range of applications such as paper-thin light source, a dome light of car and a light source for illumination, in addition to the backlight unit.

Another aspect of the present invention relates to a method of preparing the white LED. In the method of the invention, a blue LED diode is first provided, and then an emission layer comprising a red luminous body and a green luminous body is formed on the blue LED. At this time, at least one semiconductor nanocrystal and at least one inorganic phosphor have to be included in the emission layer. The emission layer is formed by using either or both of the red phosphor or red light-emitting semiconductor nanocrystals as the red luminous body and further using either or both of green phosphor or green light-emitting semiconductor nanocrystals as the green luminous body.

In the step of forming the emission layer, a mixed luminous body layer comprising both the red luminous body and green luminous body can be formed on the blue LED, or a green luminous body layer comprising a green luminous body can be first formed on the blue LED and then a red luminous body layer comprising a red luminous body can be formed on the green luminous body layer. Another method for preparing the luminous body layer can form the mixed luminous body layer of the red light-emitting semiconductor nanocrystals and green light-emitting semiconductor nanocrystals on the blue LED, and then, form the red luminous body layer or green luminous body layer on the obtained mixed luminous body layer.

If semiconductor nanocrystals utilized as a luminous body, it is possible to use semiconductor nanocrystals of multi-layered structure comprising at least two light-emitting materials. As described above, such semiconductor nanocrystals of multi-layered structure can comprise adjacent layers and the alloy interlayer comprising at least two light-emitting materials in an interface between the adjacent layers. Furthermore, the alloy interlayer may be a gradient alloy interlayer having a gradient of light-emitting material composition between the adjacent layers.

The semiconductor nanocrystals of multi-layered structure can be prepared by a procedure in which a metal precursor and a group V (i.e., group 15) or group VI (i.e., group 16) precursor are respectively introduced into a solvent with a dispersing agent, and reacted by mixing them to form the first nanocrystals. Subsequently, other metal precursors and group V or group VI precursors are introduced into a solvent and a dispersing agent, respectively, and reacted by mixing them to grow the second nanocrystals on the surface of the first nanocrystals.

Through such a procedure, the second nanocrystals are grown on the surface of the first nanocrystals, and the alloy interlayer is formed via diffusion in the interface between the first nanocrystals and the second nanocrystals. The alloy interlayer is formed by diffusion of the second nanocrystal material into the first nanocrystals in the interface between the first nanocrystals and the second nanocrystals, or by diffusion of the first nanocrystals into the second nanocrystals. In this way, it is possible to produce nanocrystals having a new structure where the alloy interlayer is formed between the first nanocrystals and the second nanocrystals due to loss of one layer as it diffuses into the other layer. At this time, if one layer that is diffused into the other layer decreases and eventually disappears, the nanocrystals provided may have the form of first nanocrystals-alloy interlayer, or alloy interlayer-second nanocrystals.

In the multi-layered structure of semiconductor nanocrystals, the same procedure can be repeated several times wherein the second nanocrystal layer is grown on the surface of the first nanocrystals, and another nanocrystal layer is grown thereon.

Examples of the metal precursor that can be used in manufacturing the semiconductor nanocrystals of multi-layered structure include, but are not limited to, dimethyl zinc, diethyl zinc, zinc acetate, zinc acetylacetonate, zinc iodide, zinc bromide, zinc chloride, zinc fluoride, zinc carbonate, zinc cyanide, zinc nitrate, zinc oxide, zinc peroxide, zinc perchlorate, zinc sulfate, dimethyl cadmium, diethyl cadmium, cadmium acetate, cadmium acetylacetonate, cadmium iodide, cadmium bromide, cadmium chloride, cadmium fluoride, cadmium carbonate, cadmium nitrate, cadmium oxide, cadmium perchlorate, cadmium phosphide, cadmium sulfate, mercury acetate, mercury iodide, mercury bromide, mercury chloride, mercury fluoride, mercury cyanide, mercury nitrate, mercury oxide, mercury perchlorate, mercury sulfate, lead acetate, lead bromide, lead chloride, lead fluoride, lead oxide, lead perchlorate, lead nitrate, lead sulfate, lead carbonate, tin acetate, tin bisacetylacetonate, tin bromide, tin chloride, tin fluoride, tin oxide, tin sulfate, germanium tetrachloride, germanium oxide, germanium ethoxide, gallium acetylacetonate, gallium chloride, gallium fluoride, gallium oxide, gallium nitrate, gallium sulfate, indium chloride, indium oxide, indium nitrate, or indium sulfate.

The group VI or V element compound, for example, includes alkyl thiol compounds such as hexane thiol, octane thiol, decane thiol, dodecane thiol, hexadecane thiol, mercapto propyl silane, etc., alkyl phosphine having sulfur-trioctylphosphine(S-TOP), sulfur-tributylphosphine(S-TBP), sulfur-triphenylphosphine(S-TPP), sulfur-trioctylamine(S-TOA), trimethylsilyl sulfur, ammonium sulfide, sodium sulfide, selenium-ntrioctylphosphine(Se-TOP), selenium-tributylphosphine(Se-TBP), selenium-triphenylphosphine(Se-TPP), tellurium-tributylphosphine(Te-TBP), tellurium-triphenylphosphine(Te-TPP), trimethylsilyl phosphine, triethylphosphine, tributylphosphine, trioctylphosphine and triphenylphosphine and tricyclohexylphosphine, arsenic oxide, arsenic chloride, arsenic sulfate, arsenic bromide, arsenic iodide, nitric oxide, nitric acid, ammonium nitrate, etc.

Examples of the solvent include a primary alkyl amine having from 6 to 22 carbon atoms, a secondary alkyl amine having from 6 to 22 carbon atoms and a tertiary alkyl amine having from 6 to 22 carbon atoms; a primary alcohol having from 6 to 22 carbon atoms, a secondary alcohol having from 6 to 22 carbon atoms and a tertiary alcohol having from 6 to 22 carbon atoms; a ketone and ester having from 6 to 22 carbon atoms; a heterocyclic compound having from 6 to 22 carbon atoms containing nitrogen or sulfur; an alkane having from 6 to 22 carbon atoms, an alkene having from 6 to 22 carbon atoms, an alkyne having from 6 to 22 carbon atoms; and trioctylphosphine and trioctylphosphine oxide.

The dispersing agent, for example, includes an alkane or alkene having from 6 to 22 carbon atoms containing a COOH group at its terminal; an alkane or alkene having from 6 to 22 carbon atoms containing a POOH group at its terminal; or an alkane or alkene having from 6 to 22 carbon atoms containing a SOOH group at its terminal; and an alkane or alkene having from 6 to 22 carbon atoms containing a NH₂ group at its terminal.

Specifically, examples of the dispersing agent may include an oleic acid, stearic acid, palmitic acid, hexyl phosphonic acid, n-octyl phosphonic acid, tetradecyl phosphonic acid, octadecyl phosphonic acid, n-octyl amine, hexadecyl amine, or the like.

Meanwhile, a diffusion velocity of the metal precursor material of the second nanocrystals can be controlled by changing a reaction temperature, a reaction time and a concentration of the metal precursor material in the second nanocrystal growth step of the method for preparing the nanocrystals of multi-layered structure. Therefore, although the first nanocrystal material having the same size is used, it is possible to obtain a material having a different emission wavelength. In the same principle, although the first nanocrystal material having the different size is used, it is also possible to obtain a material emitting a light at the same wavelength by controlling its diffusion velocity. Furthermore, the diffusion velocity in the interface between the first nanocrystals and the second nanocrystals can be controlled by changing the reaction temperature stepwise in the second nanocrystal growth step whereby it is possible to obtain a material having a different emission wavelength although the first nanocrystal material having the same size is used.

The step of forming the emission layer can be carried out by various methods. For example, the inorganic phosphor, semiconductor nanocrystals, or inorganic phosphor and semiconductor nanocrystals can be prepared in the form of a paste including an organic binder and then layered as one layer. Here, any resins may be used as the organic binder resin as long as they are transparent resins. In an embodiment, acrylic resin, silicone resin, epoxy resin, or the like can be used.

The step of layering the luminous body paste on the blue LED can be performed by any method such as drop casting, spin coating, dip coating, spray coating, flow coating, screen printing, or the like.

In the present invention, the white LED can be manufactured by any methods well known in the art to which the invention pertains. For example, the LED can be prepared by surrounding the blue LED located in a lead frame with a transparent resin matrix in which a phosphor and/or semiconductor nanocrystals are dispersed, and sealing the transparent resin matrix, electric wire and lead frame with a sealing resin.

The present invention will now be described in more detail with reference to the following examples. These examples are provided for the purpose of illustration, but are not to be construed as limiting the scope of the invention.

### PREPARATION EXAMPLE 1

### Synthesis of Green Light-Emitting Semiconductor Nanocrystals of Multi-Layered Structure

To 125 ml of flask fitted with a reflux condenser were added 16 g of trioctylamine (TOA), 0.128 g of octadecylphosphonic acid and 0.1 mmol of cadmium oxide simultaneously, and the reaction temperature was controlled to 300° C. with stirring. In addition, a Se powder was dissolved in trioctylphosphine (TOP) to prepare a Se-TOP complex solution having about 2 M of a Se concentration. Then, 2 mL of 2 M Se-TOP complex solution was rapidly added to the stirred reaction mixture to react them for about 2 minutes. Upon completion of the reaction, the temperature of the reaction mixture was lowered to a room temperature as soon as possible and the non-solvent ethanol 20 mL was added to the mixture for centrifugation. A supernatant of the centrifuged solution was discarded and the precipitate was dispersed in toluene to provide a 1% by weight solution of CdSe nanocrystal.

To 125 ml of flask fitted with a reflux condenser were added to a reaction solution of 8 g of TOA, 0.1 g of oleic acid and 0.1 mmol of zinc acetate added simultaneously, and the reaction temperature was controlled to 300° C. with stirring. The 1% by weight solution of CdSe nanocrystal synthesized above was added to the reaction solution, and then, 0.5 mL of 0.8 M S-TOP complex solution was slowly added thereto to react the components for about 1 hour, whereby ZnS nanocrystals were grown on the surface of the CdSe nanocrystals and an alloy interlayer was formed via diffusion in an interface there between. Upon completion of the reaction, the centrifugation was carried out in the same way as in the CdSe nanocrystal separation method by addition of 20 mL of the non-solvent ethanol followed by centrifugation, and the precipitate was dispersed in toluene to synthesize a 1% by weight solution (in toluene) of CdSe//ZnS nanocrystals having a multi-layered structure.

On the surface of the CdSe//ZnS nanocrystals, CdZnS was formed once again. To 125 ml of flask fitted with a reflux condenser were added 0.05 mmol of cadmium acetate, 0.1 mmol of zinc acetate, 0.43 g of oleic acid and 8 g of TOA, and the reaction temperature was controlled to 300° C. with stirring, and then, 0.5 mL of the above-synthesized 1 wt % CdSe//ZnS nanocrystal solution was introduced. Immediately thereafter, a mixture of 2 mL of TOA and 0.8 mmol of octyl thiol was slowly introduced into the solution for synthesis during about one hour, whereby nanocrystals having multi-layered structure of CdSe//ZnS/CdZnS were formed. Upon completion of the reaction, the synthesized material was separated by centrifugation as described above, and then dispersed in toluene to provide a 1.5 wt % solution of CdSe//ZnS/CdZnS in toluene.

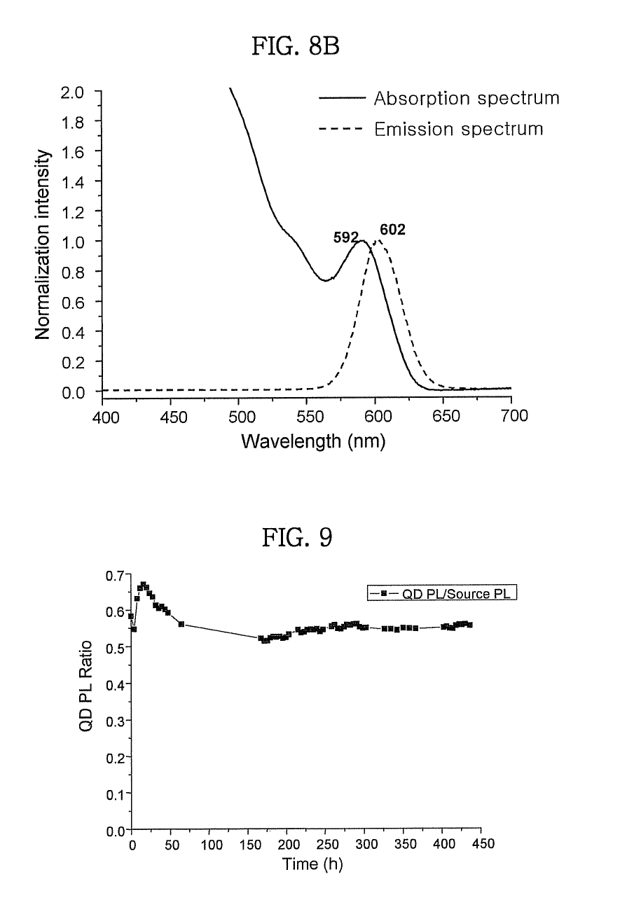

UV-VIS absorption spectrum of the green light-emitting semiconductor nanocrystals synthesized in Preparation Example 1 and excitation emission spectrum of the light excited by ultraviolet light were shown in FIG. 8A.

### PREPARATION EXAMPLE 2

### Synthesis of Red Light-Emitting Semiconductor Nanocrystals of Multi-Layered Structure

To 125 ml of flask fitted with a reflux condenser were added 32 g of TOA, 1.8 g of oleic acid and 1.6 mmol of cadmium oxide simultaneously, and the reaction temperature was controlled to 300° C. with stirring. Then, 0.2 mL of 2 M Se-TOP complex solution as synthesized in Preparation Example 1 was rapidly injected to the reaction solution, and after one minute and thirty seconds, a mixture of 6 mL of TOA and 0.8 mmol of octyl thiol was added slowly thereto. After reaction for forty minutes, 16 mL of a separately synthesized zinc oleate complex solution, described below, was introduced slowly into the reaction.

The zinc oleate complex solution was synthesized by introducing 4 mmol of zinc acetate, 2.8 g of oleic acid and 16 g of TOA into 125 ml of flask fitted with a reflux condenser and controlling the reaction temperature to 200° C. with stirring of the solution. After reducing the reaction temperature below 100° C., the zinc oleate complex solution was injected thereinto. As soon as the injection of zinc oleate complex solution is completed, a mixture of 6 mL of TOA and 6.4 mmol of octyl thiol complex solution was slowly introduced into the solution for reaction during two hours. By this process, CdSe nanocrystals were formed, CdS nanocrystals were grown on the surface thereof, and ZnS was grown once again.

Upon completion of the reaction, the temperature of the reaction mixture was rapidly reduced room temperature, 20 mL non-solvent ethanol was added to the mixture, and the resultant mixture was subjected to centrifugation. A supernatant of the centrifuged solution was discarded and the precipitate was dispersed in toluene to synthesize CdSe/CdS/ZnS nanocrystals of multi-layered structure having a size of 8 nm.

UV-VIS absorption spectrum of the red light-emitting semiconductor nanocrystals synthesized in Preparation Example 2 and excitation emission spectrum of the light excited by ultraviolet light were shown in FIG. 8B. Further, there was provided a graph showing the change of luminescence intensity versus time obtained by exciting the obtained red light-emitting semiconductor nanocrystals with a blue light source, as shown in FIG. 9. Also as shown in FIG. 9, it can be seen that the LED using the semiconductor nanocrystals of multi-layered structure maintains stable emission properties for a long period of time.

### EXAMPLE 1

### Fabrication of an LED Using Green Light-Emitting Semiconductor Nanocrystals

To 0.5 g of the 1 wt % green light-emitting semiconductor nanocrystal solution made by Preparation Example 1 was added 10 ml of a solution prepared by mixing hexane and ethanol in a volume ratio of 6:4, respectively. The resultant solution was centrifuged at 6000 rpm for 10 minutes to thereby obtain a precipitate. A chloroform solvent was added to the obtained precipitate, to prepare a solution of approximately 1% by weight of the precipitate in solution. For an epoxy resin, SJ4500 A and B resins (available from Samiun Chemicals, Inc. Korea) were previously mixed in a volume ratio of 1:1 and degassed to remove air bubbles dispersed therein. A mixture of 5 mg of the green light-emitting semiconductor nanocrystals, 0.1 mL of chloroform solution and 0.1 mL of the epoxy resin was stirred uniformly and kept under vacuum for about one hour to remove the chloroform solution. Then, about 50 μL of the mixture of green light-emitting semiconductor nanocrystals and epoxy resin thus prepared was coated on a lamp-type blue LED having a cup shape, and cured at 100° C. for three hours.

After the blue LED and the emission layer were cured in a primary cure is according to the above process, the blue LED, including the emission layer that was primarily cured by putting only the epoxy resin in a mold for molding it in the shape of lamp, was secondarily cured at 100° C. for three hours, thereby rendering the LED having the shape of lamp fabricated.

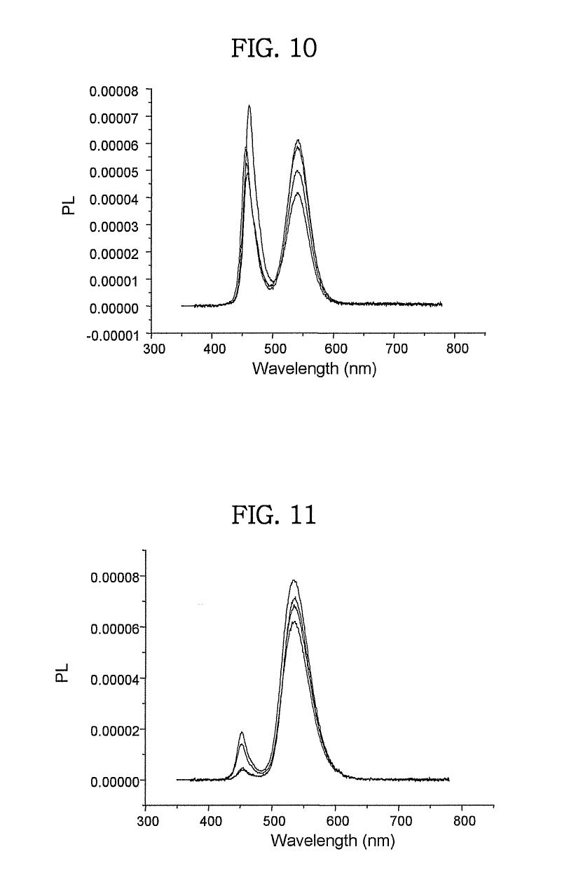

To determine a spectrum of a set of four LEDs having the lamp shape made under the same condition, the light conversion efficiency and emission spectrum were analyzed by estimating emission properties collected in an integrating sphere using ISP75 system (Instrument Systems GmbH; Munich, Germany). An emission spectrum of each of the four LEDs using the green light-emitting semiconductor nanocrystals fabricated by the method described above was shown in FIG. 10. Referring to FIG. 10, it was confirmed that the maximum emission wavelength appeared at 540 nm that was shifted by approximately 20 nm than the emission wavelength of the solution, a full width at half maximum (FWHM) was shown at about 35 nm, and the average light conversion efficiency for the LED's was about 40%.

### COMPARATIVE EXAMPLE 1

### Fabrication of LED Using a Green Inorganic Phosphor

0.05 g of TG-3540 inorganic phosphor, which is fabricated by Sarnoff Corporation and is evaluated as having the highest efficiency out of the green excitation light and showing preferred FWHM properties, and 0.1 mL of epoxy resin were stirred to uniformly mix them. Then, about 50 μL of the mixture of green inorganic phosphor and epoxy resin thus prepared was coated on a lamp-type of blue LED having a cup shape and cured in a primary cure at 100° C. for three hours.

After the blue LED and the emission layer were primarily cured according to the above process, the blue LED, including the emission layer that was primarily cured by putting only the epoxy resin in a mold for molding it in the shape of lamp, was secondarily cured at 100° C. for three hours, thereby rendering the LED having the shape of lamp fabricated.

To determine a spectrum of four LEDs having the lamp shape made under the same condition, a light conversion efficiency and emission spectrum were analyzed by estimating emission properties collected in an integrating sphere using an ISP75 system.

An emission spectrum of the four LEDs using the green inorganic phosphor fabricated by the method described above was shown in FIG. 11. It was found that the maximum emission wavelength appeared at 535 nm, FWHM was shown at about 50 nm, and the average light conversion efficiency was about 30%.

### EXAMPLE 2

### Fabrication of LED Using Red Light-Emitting Semiconductor Nanocrystals

To the red light-emitting semiconductor nanocrystals made by Preparation Example 2 was added 20 mL of a mixed solution of hexane and ethanol in a volume ratio of 6:4, respectively. The resultant solution was centrifuged at 6000 rpm for 10 minutes to obtain a precipitate. A chloroform solvent was added to the obtained precipitate, to prepare a solution of approximately 1% by weight of the precipitate. As an epoxy resin, SJ4500 A and B resins (available from Dow Corning Company) were previously mixed in a volume ratio of 1:1 and degassed to remove air bubbles suspended therein. A mixture of separated 5 mg of red light-emitting semiconductor nanocrystals, 0.1 mL of chloroform solution and 0.1 mL of the epoxy resin was stirred uniformly and kept under vacuum for about one hour to remove the chloroform solution. Then, about 50 μL of the mixture of red light-emitting semiconductor nanocrystals and epoxy resin thus prepared was coated on a lamp-type of blue LED having a cup shape and cured at 100° C. for about three hours.

After the blue LED and the emission layer were primarily cured according to the above process, the blue LED, including the emission layer that was primarily cured by putting only the epoxy resin in a mold for molding it in the shape of lamp, was secondarily cured again at 100° C. for three hours, thereby rendering the LED having the shape of lamp fabricated.

To determine a spectrum of each of four LEDs having the lamp shape made under the same condition, a light conversion efficiency and emission spectrum were analyzed by estimating emission properties collected in an integrating sphere using ISP75 system.

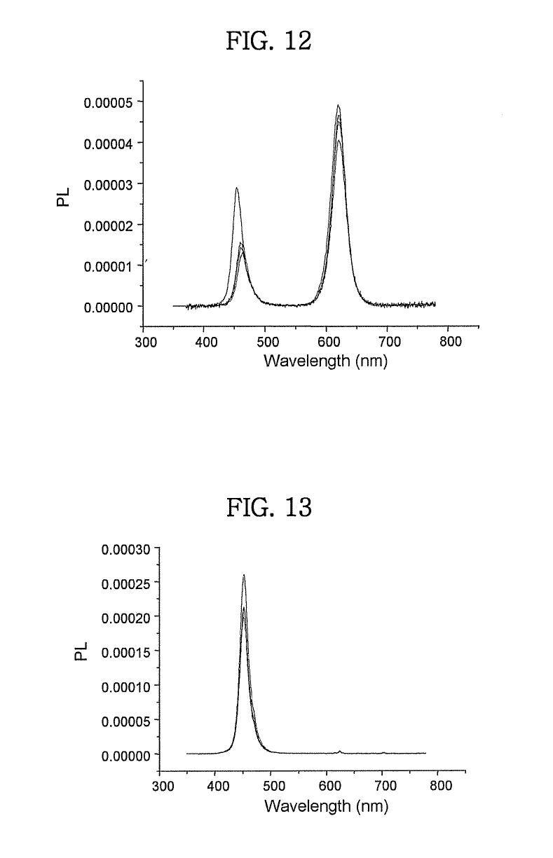

An emission spectrum of each of the four LEDs using the red light-emitting semiconductor fabricated by the method described above was shown in FIG. 12. It was confirmed that the maximum emission wavelength appeared at 620 nm that was shifted by approximately 20 nm than the emission wavelength of the solution, FWHM was shown at about 27 nm, and the average light conversion efficiency was about 20%.

### COMPARATIVE EXAMPLE 2

### Fabrication of LED Using a Red Inorganic Phosphor

0.1 g of a red inorganic phosphor of Sr—Mg—P₄O₁₆ series, that is fabricated by Sarnoff Corporation and is evaluated as having the highest efficiency out of the ultraviolet excitation light and showing good FWHM properties, and 0.1 mL of epoxy resin were stirred to mix uniformly. Then, about 50 μL of the mixture of red inorganic phosphor and epoxy resin thus prepared was coated on a lamp-type of blue LED having a cup shape and primarily cured at 100° C. for three hours.

After the blue LED and the emission layer were primarily cured according to the above process, the blue LED, including the emission layer that was primarily cured by putting only the epoxy resin in a mold for molding it in the shape of lamp, was secondarily cured at 100° C. for three hours, thereby rendering the LED having the shape of lamp fabricated.

To determine a spectrum of four LEDs having the lamp shape made under the same condition, the light conversion efficiency and emission spectrum were analyzed by estimating emission properties collected in an integrating sphere using ISP75 system.

An emission spectrum of the four LEDs using the inorganic phosphor fabricated by the method described above was shown in FIG. 13. In FIG. 13, it was found that emission properties were hardly shown in the inorganic phosphor.

### EXAMPLE 3

### Fabrication of LED Using a Mixed Emission Layer of a Green Inorganic Phosphor and Red Light-Emitting Semiconductor Nanocrystals

To the red light-emitting semiconductor nanocrystals made by Preparation Example 2 was added 10 mL of a mixed solution of hexane and ethanol in a volume ratio of 6:4 respectively. The resultant solution was centrifuged at 6000 rpm for 10 minutes to obtain a precipitate. A chloroform solvent was added to the obtained precipitate, to provide an approximately 1% by weight of solution of the precipitate. As an epoxy resin, SJ4500 A and B resins (available from Dow Corning Company) were previously mixed at the volume ratio of 1:1 and degassed to remove air bubbles trapped therein. A mixture of separated 5 mg of red light-emitting semiconductor nanocrystals, 0.05 mL of chloroform solution, 0.025 g of TG-3540 green inorganic phosphor (available from Sarnoff Corporation) and 0.1 mL of the epoxy resin was stirred uniformly and kept in a vacuum state for about one hour to remove the chloroform solution. Then, about 50 μL of the mixture of red light-emitting semiconductor nanocrystals, green inorganic phosphor and epoxy resin thus prepared was coated on a lamp-type of blue LED having a cup shape and cured at 100° C. for three hours.

After the blue LED and the emission layer were primarily cured according to the above process, the blue LED, including the emission layer that was primarily cured by putting only the epoxy resin in a mold for molding it in the shape of lamp, was secondarily cured at 100° C. for three hours, thereby providing an LED having the shape of lamp as shown FIG. 6 fabricated.

To determine a spectrum of each of four LEDs having the lamp shape made under the same condition, light conversion efficiency and emission spectrum were analyzed by estimating emission properties collected in an integrating sphere using ISP75 system.

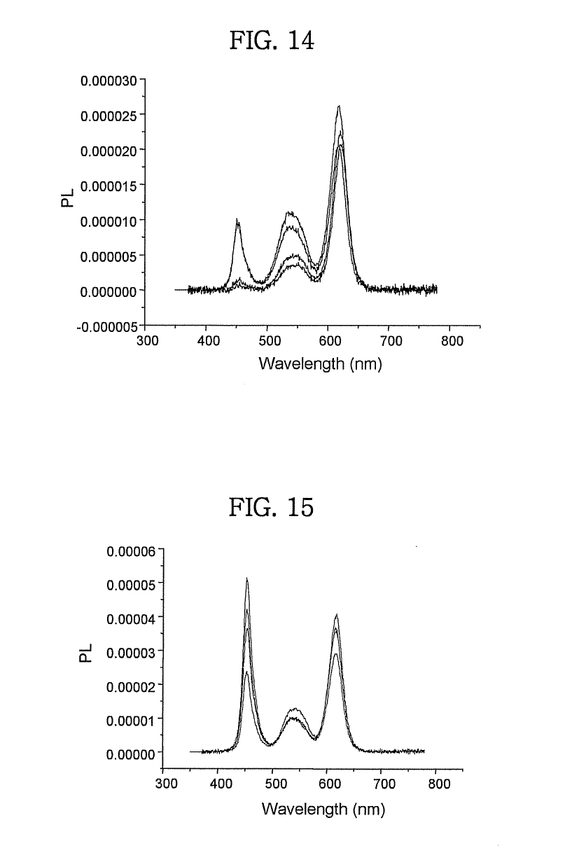

An emission spectrum of each of the four LEDs prepared using the mixed emission layer of the green inorganic phosphor and the red light-emitting semiconductor nanocrystals and fabricated by the method described above is shown in FIG. 14. It was confirmed that the emission wavelengths of the green inorganic phosphor and the red light-emitting semiconductor nanocrystals were 535 nm and 620 nm, respectively, and the average light conversion efficiency was about 30%.

### EXAMPLE 4

### Fabrication of LED having an Emission Layer of Red Light-Emitting Semiconductor Nanocrystals on a Green Inorganic Phosphor Luminous Body Layer

0.025 g of TG-3540 inorganic phosphor, which is fabricated by Sarnoff Corporation and is evaluated as having the highest efficiency out of the blue excitation light and showing good FWHM properties, and 0.1 mL of epoxy resin were stirred to provide a uniform mixture. Then, about 10 mL of the mixture of green inorganic phosphor and epoxy resin so prepared was coated on a lamp-type of blue LED having a cup shape and primarily cured at 100° C. for three hours.

To the red light-emitting semiconductor nanocrystals made by Preparation Example 2 was added 10 mL of a mixed solution of hexane and ethanol in a volume ratio of 6:4, respectively. The resultant solution was centrifuged at 6000 rpm for 10 minutes to obtain a precipitate. Chloroform was added to the obtained precipitate, to provide an approximately 1% by weight solution of the precipitate. For an epoxy resin, SJ4500 A and B resins (available from Dow Corning Company) were previously mixed in a volume ratio of 1:1 and degassed to remove air bubbles trapped therein. A mixture of separated 5 mg of red light-emitting semiconductor nanocrystals, 0.05 mL of chloroform solution and 0.1 mL of the epoxy resin was stirred to uniformly mix them and kept in a vacuum state for about one hour to remove the chloroform solution. Then, about 10 mL of the mixture of red light-emitting semiconductor nanocrystals and epoxy resin thus prepared was coated on the green inorganic phosphor emission layer made above and primarily cured at 100° C. for three hours.

After the blue LED and the emission layer were primarily cured according to the above process, the blue LED, including the emission that was cured primarily by putting only the epoxy resin in a mold for molding it in the shape of lamp, was secondarily cured at 100° C. for three hours, thereby rendering the LED having the shape of lamp fabricated as shown in FIG. 7.

To determine the spectrum of each of four LEDs having the lamp shape made under the same condition, a light conversion efficiency and emission spectrum were analyzed by estimating emission properties collected in an integrating sphere using ISP75 system.

An emission spectrum of each of the four LEDs prepared using the green inorganic phosphor emission layer and the red light-emitting semiconductor nanocrystals and fabricated by the method described above was shown in FIG. 15. It was confirmed that the emission wavelengths of the green inorganic phosphor and the red light-emitting semiconductor nanocrystals were 535 nm and 620 nm, respectively, and the average light conversion efficiency was about 35%.

As set forth above, the white LED of the present invention thus employs semiconductor nanocrystals of multi-layered structure as a phosphor on a blue LED, and has excellent color purity and high luminous efficiency so that it is suitable for use as a light source for a backlight unit (e.g., in an LED display).

Furthermore, the semiconductor nanocrystals of multi-layered structure used in the present invention have excellent light stability, and therefore, where a blue LED is used as an excitation light source, the semiconductor nanocrystal is expected to maintain emission properties for a longer time than a non-multilayered semiconductor nanocrystal. Also, where the semiconductor nanocrystals of multi-layered structure are used together with the inorganic phosphor, they can absorb only a part of light from the excitation light source, thereby prolonging the life span of an LED prepared according to the invention.

In addition, the semiconductor nanocrystals of multi-layered structure can absorb energy from a wavelength range similar to the emission wavelength. Thus, if they are used with the inorganic phosphor, they can again absorb and emit lower energy light of a wavelength as emitted from the inorganic phosphor so that this lower energy emission acts as an excitation wavelength, which also can prolong the life span of the semiconductor nanocrystal.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A white light-emitting diode (LED) in which an emission layer comprising a red luminous body and a green luminous body is formed on a blue LED, wherein the emission layer comprises both of at least one inorganic phosphor and at least one semiconductor nanocrystal.

2. The white LED according to claim 1, wherein the red luminous body comprises either or both of a red phosphor or red light-emitting semiconductor nanocrystals, and the green luminous body comprises either or both of a green phosphor or green light-emitting semiconductor nanocrystals.

3. The white LED according to claim 1, wherein the emission layer is a mixed luminous body layer comprising the red luminous body and the green luminous body.

4. The white LED according to claim 1, wherein the emission layer comprises:
a green luminous body layer comprising the green luminous body formed on the blue LED; and
a red luminous body layer comprising the red luminous body formed on the green luminous body layer on a side opposite the blue LED.

5. The white LED according to claim 1, wherein the emission layer comprises:
a mixed luminous body layer comprising the red luminous body and the green luminous body formed on the blue LED; and
a red luminous body layer comprising the red luminous body, formed on the mixed luminous body layer on a side opposite the blue LED.

6. The white LED according to claim 1, wherein the emission layer comprises:
a mixed luminous body layer comprising the red luminous body and the green luminous body formed on the blue LED; and
a green luminous body layer comprising the green luminous body, formed on the mixed luminous body layer on a side opposite the blue LED.

7. The white LED according to claim 1, wherein at least one of the green light-emitting semiconductor nanocrystals and the red light-emitting semiconductor nanocrystals is a semiconductor nanocrystal comprising a multi-layered structure comprising at least two light-emitting materials.

8. The white LED according to claim 7, wherein the semiconductor nanocrystals of multi-layered structure comprises adjacent layers of light-emitting materials and an alloy interlayer comprising at least two light-emitting materials in an interface between adjacent layers.

9. The white LED according to claim 8, wherein the alloy interlayer is a gradient alloy interlayer having a gradient of light-emitting material composition.

10. The white LED according to claim 7, wherein at least one of the layers of the semiconductor nanocrystals of multi-layered structure comprises an alloy interlayer comprising at least two light-emitting materials.

11. The white LED according to claim 10, wherein the alloy interlayer is a gradient alloy interlayer having a gradient of light-emitting material composition.

12. The white LED according to claims 1, wherein the semiconductor nanocrystals are selected from the group consisting of a group II-VI compound, a group III-V compound, a group IV-VI compound, a group IV compound, and a mixture of the compounds.

13. The white LED according to claim 12, wherein the group II-VI compound is selected from the group consisting of binary compounds including CdSe, CdTe, ZnS, ZnSe, ZnTe, ZnO, HgS, HgSe, HgTe; ternary compounds including CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, and HgZnSe; and quaternary compounds including HgZnTe, CdZnSeS, CdZnSeTe, CdZnSTe, CdHgSeS, CdHgSeTe, CdHgSTe, HgZnSeS, HgZnSeTe, and HgZnSTe,
the group III-V compound is selected from the group consisting of binary compounds including GaN, GaP, GaAs, GaSb, AlN, AlP, AlAs, AlSb, InN, InP, InAs, and InSb; ternary compounds including GaNP, GaNAs, GaNSb, GaPAs, GaPSb, AlNP, AlNAs, AlNSb, AlPAs, AlPSb, InNP, InNAs, InNSb, InPAs, and InPSb; and quaternary compounds including GaAlNP, GaAlNAs, GaAlNSb, GaAlPAs, GaAlPSb, GaInNP, GaInNAs, GaInNSb, GaInPAs, GaInPSb, INAlNP, InAlNAs, InAlNSb, InAlPAs, and InAlPSb,
the group IV-VI compound is selected from the group consisting of binary compounds including SnS, SnSe, SnTe, PbS, PbSe, and PbTe; trinary compounds including SnSeS, SnSeTe, SnSTe, PbSeS, PbSeTe, PbSTe, SnPbS, SnPbSe, and SnPbTe; and quaternary compound including SnPbSSe, SnPbSeTe, and SnPbSTe; and
the group IV compound is selected from the group consisting of single element compound including Si and Ge; and binary compounds including SiC and SiGe.

14. The white LED according to claims 1, wherein the semiconductor nanocrystals have a shape selected from the group consisting of a sphere, tetrahedron, cylinder, rod, triangle, disc, tripod, tetrapod, cube, box, star and tube.

15. A backlight unit comprising the white LED according to claim 1.

16. A display device comprising the backlight unit according to claim 15.

17. A method for producing a white LED in which an emission layer comprising a red luminous body and a green luminous body is formed on a blue LED, which comprises the steps of:
(a) providing the blue LED; and
(b) forming the emission layer comprising both at least one semiconductor nanocrystal and at least one inorganic phosphor on the blue LED.

18. The method for producing the white LED according to claim 17, wherein the step (b) forms the emission layer comprising the red luminous body and the green luminous body on the blue LED, and forms a luminous body layer by using either or both of a red phosphor or red light-emitting semiconductor nanocrystals as the red luminous body and further using either or both of a green phosphor or green light-emitting semiconductor nanocrystals as the green luminous body.

19. The method for producing the white LED according to claim 18, wherein the step (b) forms a mixed luminous body layer comprising the red luminous body and the green luminous body on the blue LED.

20. The method for producing the white LED according to claim 18, wherein the step (b) comprises the steps of:
forming a green luminous body layer on the blue LED; and
forming a red luminous body layer on the green luminous body layer on a side opposite the blue LED.

21. The method for producing the white LED according to claim 18, wherein the step (b) comprises the steps of:
forming a mixed luminous body layer comprising the red light-emitting semiconductor nanocrystals and the green light-emitting semiconductor nanocrystals on the blue LED; and
forming a red luminous body layer on the mixed luminous body layer on a side opposite the blue LED.

22. The method for producing the white LED according to claim 18, wherein the step (b) comprises the steps of:
forming a mixed luminous body layer comprising the red luminous body and the green luminous body on the blue LED; and
forming a green luminous body layer comprising the green luminous body on the mixed luminous body layer on a side opposite the blue LED.

23. The method for producing the white LED according to claim 18, wherein the green light-emitting semiconductor nanocrystals and red light-emitting semiconductor nanocrystals are semiconductor nanocrystals of multi-layered structure comprising at least two light-emitting materials.

24. The method for producing the white LED according to claim 23, wherein the semiconductor nanocrystals of multi-layered structure comprise adjacent layers having an alloy interlayer comprising at least two light-emitting materials in an interface between the adjacent layers.

25. The method for producing the white LED according to claim 24, wherein the alloy interlayer is a gradient alloy interlayer having a gradient of light-emitting material composition.

26. The method for producing the white LED according to claim 23, wherein at least one of the layers of the semiconductor nanocrystals of multi-layered structure comprises an alloy interlayer comprising at least two light-emitting materials.

27. The method for producing the white LED according to claim 26, wherein the alloy interlayer is a gradient alloy interlayer having a gradient of light-emitting material composition.

28. The method for producing the white LED according to claim 18, wherein the step (b) comprises the steps of preparing the phosphor, semiconductor nanocrystals, or the phosphor and semiconductor nanocrystals in the form of a paste including an organic binder, and layering the paste.

29. The method for producing the white LED according to claim 28, wherein the organic binder is an acrylic resin, silicone resin, or epoxy resin.

30. The method for producing the white LED according to claim 28, wherein the layering step is performed by drop casting, spin coating, dip coating, spray coating, flow coating, or screen printing.
